(19) United States
(12) Patent Application Publication
(10) Pub. No.: US 2026/0190370 A1
(43) Pub. Date: Jul. 2, 2026

(54) HIGH-DENSITY LOW-K DIELECTRIC LAYER

(71) Applicant: Taiwan Semiconductor Manufacturing Company, Ltd., Hsinchu (TW)

(72) Inventors: Wan-Yi Kao, Hsinchu County (TW); Hsin-Hsiang Huang, New Taipei City (TW); Chunyao Wang, Hsinchu County (TW); Tze-Liang Lee, Hsinchu (TW)

(21) Appl. No.: 19/006,371

(22) Filed: Dec. 31, 2024

(51) Int. Cl. H10D 30/01; C23C 16/02; C23C 16/455; C23C 16/56; H01L 21/02; H10D 30/00; H10D 64/23

(52) U.S. Cl. CPC H10D 30/0196; C23C 16/0227; C23C 16/45525; C23C 16/56; H10D 30/509; H10P 14/6519; H10P 14/6532; H10P 14/6681; H10P 14/683; H10D 64/258; H10P 14/6339

(57) ABSTRACT

A method according to the present disclosure includes depositing a precursor on a material layer, oxidizing the precursor on the material layer, and performing a plasma treatment of the oxidized precursor to form a low dielectric constant (low-k) dielectric layer. The precursor includes a disilacyclobutane backbone.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

Dielectric material is widely used to form various structures in a semiconductor device. For example, a dielectric layer may be formed to serve as an isolation feature or a protective layer. A desirable isolation feature has a low dielectric constant to reduce parasitic capacitance while a desirable protective layer may include a greater density to resist etching.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method of identifying a potential precursor for a low-dielectric-constant and high-density dielectric layer, according to one or more aspects of the present disclosure.

FIG. 2 illustrates Table 1 that includes various silicon bonds and their properties, according to one or more aspects of the present disclosure.

FIG. 3 illustrates a design-of-experiment (DOE) scaling chart, according to one or more aspects of the present disclosure.

FIG. 4 illustrates a molecular structure that includes a disilacyclobutane backbone, according to one or more aspects of the present disclosure.

FIG. 5 illustrates Table 2 that illustrates various functional groups in the molecular structure in FIG. 4, according to one or more aspects of the present disclosure.

FIG. 6 illustrates a molecular structure of 1,1,3,3-tetrachloro-1,3-disilacyclobutane, according to one or more aspects of the present disclosure.

FIG. 7 illustrates a molecular structure of 1,3-bis(dimethylamino)-1,3-ethoxyl-1,3-disilacyclobutane, according to one or more aspects of the present disclosure.

FIG. 8 illustrates a flowchart of a method of depositing a dielectric layer using precursors according to one or more aspects of the present disclosure.

FIG. 9 includes a chart comparing etch resistance and a dielectric constant of the dielectric material of the present disclosure to those of state-of-the-art dielectric materials.

FIG. 10 includes a chart comparing a density and a dielectric constant of the dielectric material of the present disclosure to those of state-of-the-art dielectric materials.

FIG. 11 illustrates a flowchart of a method of forming a gate-all-around transistor, according to one or more aspects of the present disclosure.

FIGS. 12-30 illustrate fragmentary cross-sectional views of a work-in-progress (WIP) structure during a fabrication process according to the method of FIG. 11, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

In the semiconductor art, a low-dielectric-constant (low-k) material refers to a material that has a relative dielectric constant smaller than that of silicon dioxide. Silicon dioxide is selected as the baseline for comparison because a wide range of methods can be performed to economically deposit a silicon dioxide layer. The continued scaling of microelectronic devices is made possible by implementation of low-k dielectric materials. As components in a semiconductor device have gotten closer together, insulating dielectrics have thinned to a point where charge build-up and crosstalk impact the performance of the semiconductor device. Adoption of low-k dielectrics generally reduces parasitic capacitance and enables faster switching speed. However, adoption of low-k dielectrics is not without concerns and limitations. As a result of measures to reduce the dielectric constant of a low-k dielectric, the low-k dielectric layer may have a smaller density and a reduced etch resistance. When a deposited low-k dielectric layer is not protected by a more etch resistant material, etching process may substantially damages the low-k dielectric layer. If the low-k dielectric layer serves any insulation or protective function, such damages may result in device failures. For the foregoing reasons, the semiconductor industry continues to look for a low-k dielectric layer that also reasonably resists etching.

The present disclosure includes several aspects. In a first aspect, the present disclosure provides a method of identifying a potential precursor for a low-dielectric-constant and high-density dielectric layer. The method includes populating a library of precursors, performing a structure-based simulation to determine a first pool of candidate precursors, performing a process-based simulation to determine a second pool of candidate precursors, and performing further tests on the second pool of candidate precursors. In a second aspect, the present disclosure provides example precursors identified using the method summarized above. In a third aspect, the present disclosure provides a method of depositing a dielectric layer using the example precursors. In some examples, the method includes depositing a silicon-containing precursor over a target surface, performing an oxidation process on the deposited silicon-containing precursor, and performing a densification process on the oxidized silicon-containing precursor. In a fourth aspect, the present disclosure provides an example process of fabricating a multi-gate device where the example process integrates the steps of forming the low-dielectric constant and high-density dielectric layer.

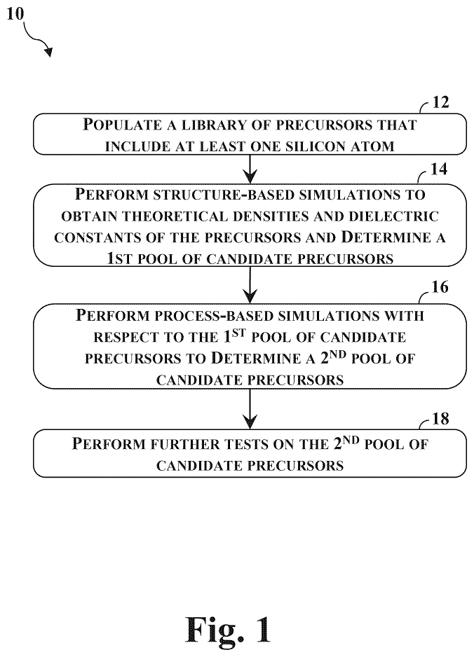

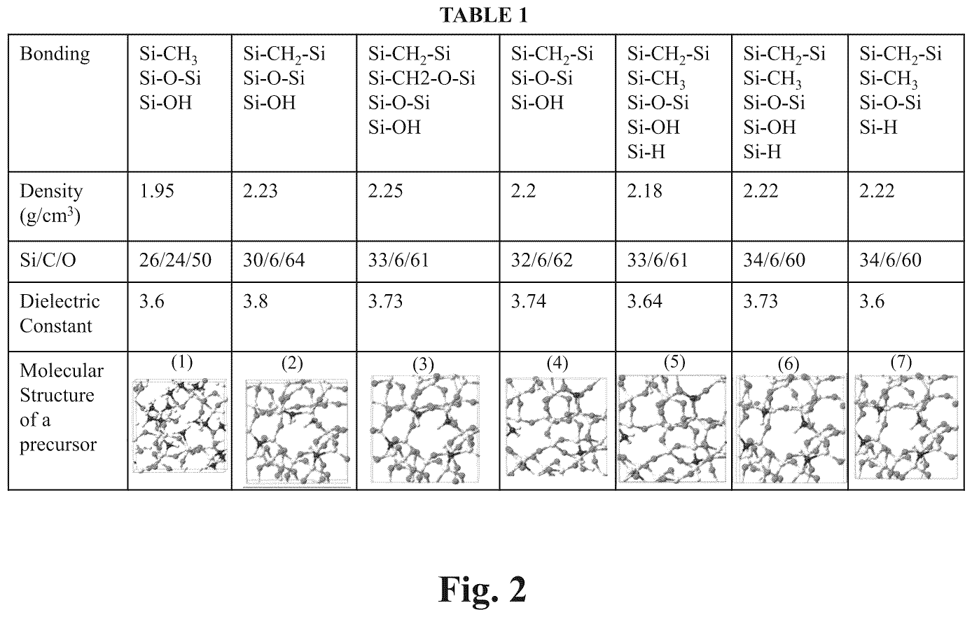

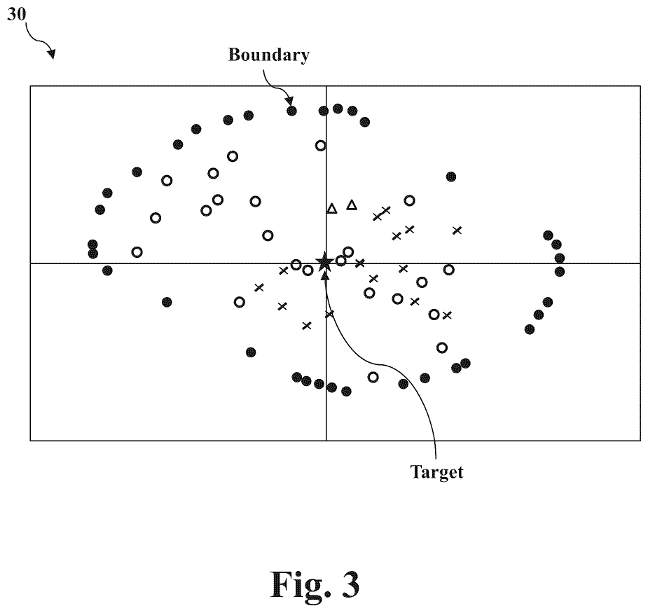

The first aspects of the present disclosure will now be described in more detail. In that regard, FIG. 1 is a flowchart illustrating method 10 of identifying a potential precursor for a low-dielectric-constant and high-density dielectric layer. Method 10 is merely an example and is not intended to limit the present disclosure to what is explicitly illustrated in method 10. Additional steps can be provided before, during and after method 10, and some steps described can be replaced, eliminated, or moved around for additional embodiments of the method. Not all steps are described herein in detail for reasons of simplicity. Method 10 is described below in conjunction with FIG. 2-3.

Referring to FIG. 1, method 10 includes a block 12 where a library of precursors that include at least one silicon atom are populated. In some embodiments, the library is populated by importing molecules that includes silicon. Because the precursor is intended to be deposited using atomic layer deposition (ALD), which is a self-limiting gas-phase chemical deposition process, the precursors in the library may only include small molecular weight molecules that may be supplied in gas phase at a reasonable temperature, such as between room temperature (i.e., about 20° C.) and about 500° C. Besides silicon atoms, the precursors in the library may include carbon atoms or alkyl group that are known to reduce ionization or polarization. Additionally, because method 10 is intended for identifying precursors that are not used in the industry or academically, precursors that are commercialized or reported in academic research papers may be excluded from the library. The library is populated in a way that information of the precursors is compatible with and retrievable by simulation tools used for subsequent simulation steps.

Referring to FIGS. 1 and 2, method 10 includes a block 14 where structure-based simulations are performed to obtain theoretical densities and dielectric constants of the precursors in the library and to determine a first pool of candidate precursors. At block 12, each of the precursors in the library is broken down into bonding groups. Table 1 in FIG. 2 illustrates 7 precursors that are each broken down into bonding groups. For example, precursor (1) includes a silicon-methyl (Si—CH₃) bonding group, a siloxane (Si—O—Si) bonding group and a silanol (Si—OH) bonding group. Based on molecular dynamic simulations and experimental data, precursor (1) has a density of about 1.95 g/cm³, a dielectric constant of about 3.6, and silicon-to-carbon-to-oxygen ratio of about 26:24:50. Similar molecular dynamics simulations may be performed to all of the precursors in the library to determine their theoretical densities, molecular ratios, and dielectric constants. To ensure that the precursors can perform at the same level with or outperform commercially available precursors, the densities and dielectric constants of the precursors are compared to a pre-determined density and a pre-determined dielectric constant. In some embodiments, the pre-determined density is about 2.15 g/cm³ and the pre-determined dielectric constant is about 3.7. When a precursor in the library has a density equal to or greater than the pre-determined density and a dielectric constant equal to or smaller than the pre-determined dielectric constant, it is determined that this precursor belongs to the first pool of candidate precursors. In the embodiments described above, only precursors (5) and (7) in Table 1 belong to the first pool of candidate precursors because their densities are greater than the pre-determined density and their dielectric constants are smaller than the pre-determined dielectric constant.

Referring to FIG. 1, method 10 includes a block 16 where process-based simulations are performed to determine a second pool of candidate precursors. At block 16, an ALD deposition process is simulated using molecular dynamics tools to determine theoretical parameters such as process temperatures, carbon contents before and after the deposition process, nitrogen contents before and after the deposition process. In some implementations, molecular dynamics tools may identify more than one possible ALD deposition processes for a candidate precursor in the first pool of candidate precursors. To narrow the first pool of candidate precursors into a smaller second pool of candidate precursors, these parameters from the process-based simulation are given weights based on their desirability and considered as a whole when assessing the candidate precursors. For example, a precursor with a lower ALD process temperature is more advantageous than another precursor with a higher ALD process temperature. Generally, a process temperature reflects the activation energy (Ea) or bond dissociation energy (BDE) required for the deposition of the precursor. For another example, a greater carbon content is usually associated with a lower dielectric constant. For yet another example, a greater nitrogen content is usually associated with a greater dielectric constant. At block 16, candidate precursors that may be deposited using an ALD process, do not undergo substantial nitrogen content increase (i.e., greater than 50%) and do not undergo substantial carbon content decrease (i.e., greater than 50%) are determined to belong to the second pool of candidate precursors.

Referring to FIGS. 1 and 3, method 10 includes a block 18 where further tests on the second pool of candidate precursors are performed. In some embodiments, such further tests may include etch resistance testing of dielectric layers deposited using the candidate precursors in the second pool. In an example etch resistance test, a dielectric layer is deposited over a sample layer that includes a semiconductor material (e.g., silicon) or a dielectric material (e.g., silicon oxide). An ashing process that uses oxygen is then performed to the deposited dielectric layer. The thickness that is removed during a given amount of time is then measured. The thickness of the dielectric layer removed during the give amount of time may be referred to as ashing damage and provides an indicator of an etch resistance of the dielectric. Parameters such as densities, dielectric constant, carbon contents, etch resistance, process conditions are given different weighing factors based on their desirability or process compatibility. The weighed parameters are then assessed as a whole to determine a list of prime precursors. Due to the number of parameters and different weighing factors assigned to the parameters, the amount of calculation and analysis require use of a computer system running an artificial intelligence engine. FIG. 3 includes a design-of-experiments (DOE) scaling chart 30 that graphically represents the analysis and machine learning performed by the computer system. The solid black dots in the DOE scaling chart 40 define a boundary that is derived from the pre-determined ranges of parameters and corresponding weighing factors. In the DOE scaling chart, the star represents a target that outperforms its peers in all categories. The crosses, hollow circles and triangles represents different test datapoints. At block 18, precursors that have a scaling datapoint on or closest to the target are included in the list of prime precursors.

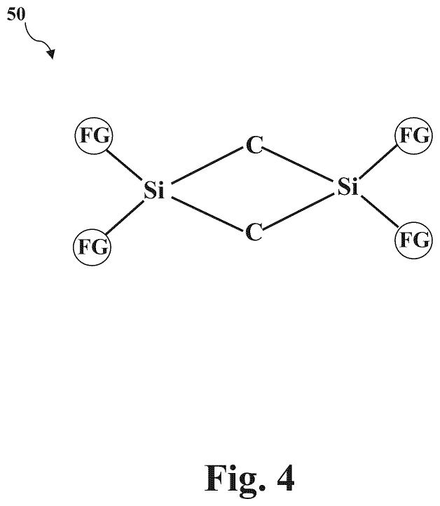

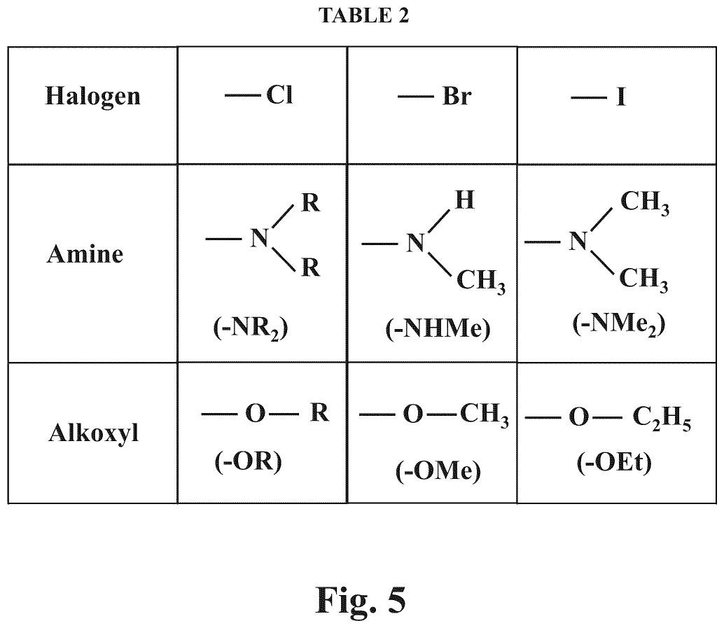

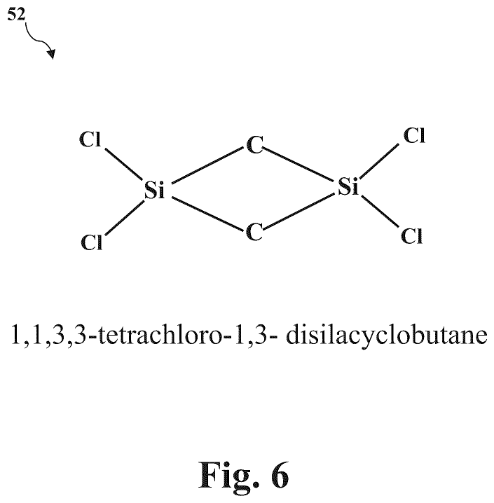

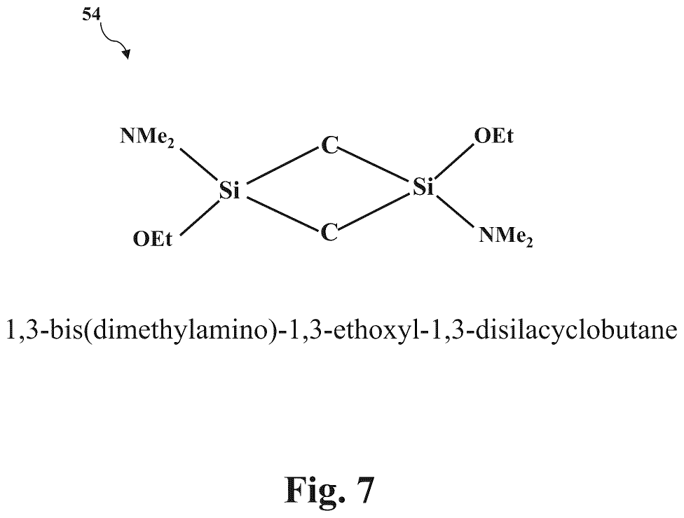

The second aspect of the present disclosure is directed to the prime precursors identified using method 10 described above. FIG. 4 illustrates a generic molecular structure 50 that includes a disilacyclobutane backbone and four functional groups (FGs). FIG. 5 includes Table 1 that includes example functional groups that may be included in the generic molecular structure 50. FIG. 6 illustrates a molecular structure of a first example precursor 52. FIG. 7 illustrates a molecular structure of a second example precursor 54.

Performance of method 10 of the present disclosure indicates that precursors that outperform all precursors in the library share a generic molecular structure 50 shown in FIG. 4. The generic molecular structure 50 in FIG. 4 includes a disilacyclobutane backbone which includes two silicon atoms linked by two carbon bridges. Advantages of having the disilacyclobutane backbone have sound explanations. The carbon bridges remain intact during deposition. Each of the carbon atoms in the carbon bridges is bonded to two silicon atoms, which reduces sites that can be replaced by nitrogen-containing amine group. As described above, it has been observed that an increased nitrogen content may lead to higher dielectric constant and an increased in carbon content may lead to greater etch resistance. Each of the two silicon atoms is further bonded to two functional groups. The functional groups (FGs) on the disilacyclobutane backbone may include those shown in Table 2 in FIG. 5. As illustrated in Table 2, the functional groups may include halogens, amine groups, or alkoxyl groups. Example halogens may include chlorine (—Cl), bromine (—Br), or iodine (—I). Example amine groups may include methyl amine (—NHMe) or dimethyl amine (—NMe₂). Example alkoxyl groups may include a methoxyl group (—OMe) or an ethoxyl group (—OEt). While it is possible for at last one of the 4 functional groups to be different from at least one of the other functional groups, experimental results show that the density of the resulting dielectric layer tends to be higher when the functional groups are all the same or present a form of symmetry. Further research may help identify improved combinations of functional groups bonded to the two silicon atoms in the disilacyclobutane backbone.

FIGS. 6 and 7 illustrates a first example precursor 52 and a second example precursor 54 that come out on top when method 10 is performed to the library of precursors. The first example precursor 52 in FIG. 6 is 1,1,3,3-tetrachloro-1,3-disilacyclobutane. In terms of the generic molecular structure 50 in FIG. 4, the first example precursor 52 is an embodiment of the generic molecular structure 50 when all four functional groups are chlorine (—Cl). The first example precursor 52 has a ratio of carbon atoms to nitrogen atoms is about 2:4 or one half (0.5). The second example precursor 54 in FIG. 7 is 1,3-bis(dimethylamino)-1,3-ethoxyl-1,3-disilacyclobutane. In terms of the generic molecular structure 50 in FIG. 4, the second example precursor 54 is an embodiment of the generic molecular structure 50 when each of the two silicon atoms is bonded to a dimethyl amine (—NMe₂) group and an ethoxyl group (—OEt). The second example precursor 54 has a ratio of carbon atoms to nitrogen atoms is about 2:2 or one (1).

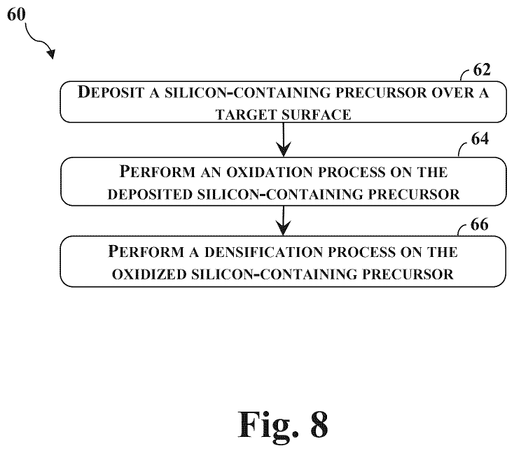

Referring to FIG. 8, the third aspect of the present disclosure is directed to a method 60 of depositing a dielectric layer using example precursors shown or represented in FIGS. 4, 6 and 7. Method 60 is merely an example and is not intended to limit the present disclosure to what is explicitly illustrated in method 60. Additional steps can be provided before, during and after method 60, and some steps described can be replaced, eliminated, or moved around for additional embodiments of the method. Not all steps are described herein in detail for reasons of simplicity.

Method 60 includes a block 62 where a silicon-containing precursor is deposited over a target surface. In some embodiments, the target surface may include a surface of a semiconductor feature or dielectric feature. For example, the target surface may include a surface of a feature formed of silicon, silicon germanium, germanium, silicon oxide, silicon nitride, silicon oxynitride, silicon oxycarbonitride, silicon oxycarbide, or silicon carbonitride. To be suitable for the subsequent atomic layer deposition process, the target surface may include dangling bonds, such as hydroxyl groups.

When the first example precursor 52 is deposited at block 62, the first example precursor 52 is allowed to contact the target surface such that chlorine groups on the first example precursor 52 are allowed to interact and bond to the hydroxyl groups on the target surface or chemisorb to the target surface. In some instances, the substrate is mounted on a chuck maintained at a temperature between about 300° C. and about 600° C. at block 62. The first example precursor 52 that is not bonded to the target surface is then removed by purging. After the purging, a reactive gas, such as ammonia (NH₃) is directed to the target surface to replace the unreacted chlorine groups on the first example precursor 52. The deposition of the first example precursor 52, the purging and supply of the reactive gas constitute a deposition cycle. The deposition cycle may be repeated about 5 times and about 20 times in an atomic layer deposition (ALD) process. In some alternative embodiments, ammonia is first allowed to react with the dangling bonds on the target surface or chemisorb on the target surface. The excess ammonia is then purged. Subsequently, the first example precursor 52 is allowed to interact or react with the amine groups on the target surface. The steps in these alternative embodiments may also constitute a deposition cycle, which is to be repeated in the ALD process.

When the second example precursor 54 is deposited at block 62, the second example precursor 54 is allowed to contact the target surface such that ethoxyl groups on the second example precursor 54 are allowed to interact and bond to the hydroxyl groups on the target surface or to chemisorb to the target surface. The second example precursor 54 that is not bonded to the target surface is then removed by purging. Because the second example precursor 54 includes dimethyl amine groups, deposition of the second example precursor 54 does not require directing ammonia (NH₃) to the target surface after purging or before the provision of the second example precursor 54. The deposition of the second example precursor 54 and the purging constitute a deposition cycle. The deposition cycle may be repeated about 5 times and about 20 times in the ALD process.

Method 60 includes a block 64 where an oxidation process is performed on the deposited silicon-containing precursor. The oxidation process at block 64 may include a thermal oxidation process or a plasma oxidation process. In a thermal oxidation process, an oxygen-containing gas, such as water (H₂O) or oxygen (O₂), is allowed to react with a silicon atom bonded to an amine group (—NH₂) or a dimethyl amine (—NMe₂) group or a silicon atom bonded to a silyl methyl group (—CH₂—Si). Because thermal oxidation breaks the silicon-nitrogen (Si—N) bond easier than it does the silicon-carbon (S—C) bond, it tends to increase a carbon to nitrogen (C/N) ratio. This is so because the activation energy required to break the silicon-nitrogen (Si—N) bond is lower and breaking it requires a lower temperature. In a plasma oxidation, remotely generated plasma of an oxygen-free gas, such as nitrogen, is directed to the target surface to break the silicon-nitrogen (Si—N) bond or the silicon-carbon (Si—C) bond. Because plasma oxidation breaks silicon-carbon (Si—C) bond easier than it does the silicon-nitrogen (Si—N) bond, it tends to decrease a carbon to nitrogen (C/N) ratio. This is so because the enthalpy difference required to break the silicon-nitrogen (Si—N) bond is greater and breaking it requires more energy. In some embodiments, at block 64, the substrate is mounted on a chuck maintained at a temperature between about 300° C. and about 600° C.

Method 60 includes a block 66 where a densification process is performed on the oxidized silicon-containing precursor. In some embodiments, the densification process may include use of high-density induction-coupled plasma (ICP) of hydrogen (H⁺). In some instances, the densification process may introduce an oxygen atom in a Silicon-carbon-silicon (Si—C—Si) bonding and form silicon-carbon-oxygen-silicon (Si—C—O—Si) bonding, such as Si—CH₂—O—Si. The silicon-carbon-oxygen-silicon bonding includes two silicon atoms connected by a carbonyl (CO) group.

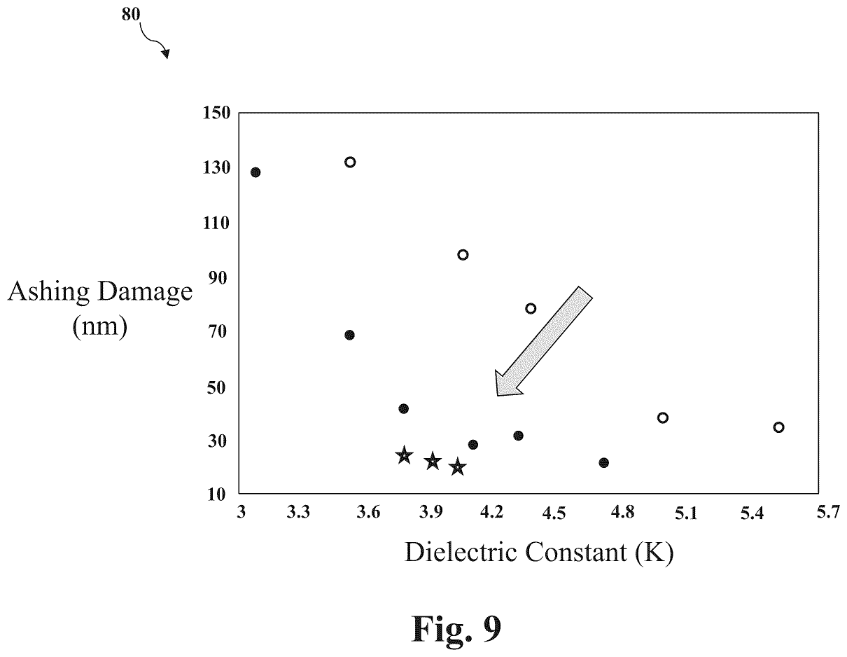

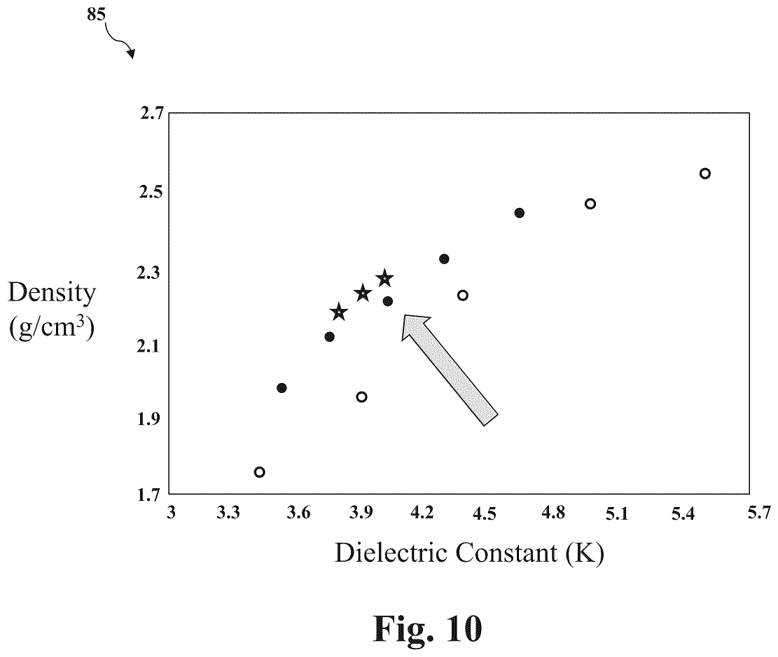

Tests have been performed on the dielectric layer deposited using method 60. FIG. 9 illustrates a chart 80 that compares etch resistance and a dielectric constant of the dielectric material of the present disclosure to those of the state-of-the-art dielectric layers. FIG. 10 illustrates a chart 85 that compares a density and a dielectric constant of the dielectric material of the present disclosure to those of state-of-the-art dielectric materials. Reference is first made to chart 80 in FIG. 9. Chart 80 charts ashing damages (measured in nanometers (nm)) against dielectric constant. In FIG. 9, the hollow dots represent data points of conventional low-k dielectric layers formed using ALD, solid dots represents data points of low-dielectric layers formed using chemical vapor deposition (CVD), and solid stars represent data points of low-k dielectric layers deposited using precursors shown in FIGS. 4, 6 and 7. In chart 80, the solid dots generally fall below and to be left of the hollow dots, this indicates that that the conventional CVD low-k dielectric layers tend to have better etch resistance and lower dielectric constants than the conventional ALD low-k dielectric layers. It is noted that while ALD provides better step coverage and thickness uniformity, deposition of conventional ALD low-k dielectric layers involves reacting ammonia with a silicon-containing precursor with carbon atoms that can be cleaved off the backbone or replaced by nitrogen atoms. The result is that most low-k dielectric layers deposited using conventional precursors and ALD process have higher-than-expected dielectric constants. This also explains why most state-of-the-art and commercially available low-k dielectric layers are deposited using CVD, rather than ALD. In chart 80, the solid stars fall below and to the left of the solid dots, which indicates that the low-k dielectric layers deposited using precursors shown in FIGS. 4, 6 and 7 out-perform the state-of-the-art CVD low-k dielectric layers in terms of etch resistance and dielectric constant.

Reference is now made to chart 85 in FIG. 10. Chart 85 charts density (measured in g/cm³) against dielectric constant. In FIG. 10, the hollow dots represent data points of conventional low-k dielectric layers formed using ALD, solid dots represents data points of conventional low-dielectric layers formed using CVD, and solid stars represent data points of low-k dielectric layers deposited using precursors shown in FIGS. 4, 6 and 7. In chart 80, the solid dots generally fall above and to be left of the hollow dots, this indicates that that the conventional CVD low-k dielectric layers tend to have greater densities and lower dielectric constants than the conventional ALD low-k dielectric layers. This once again shows that conventional CVD low-k dielectric layers usually outperform conventional ALD low-k dielectric layers. This also explains why conventional CVD low-k dielectric layers dominate the market even though ALD provides various benefits. In chart 85, the solid stars fall above and to the left of the solid dots, which indicates that the low-k dielectric layers deposited using precursors shown in FIGS. 4, 6 and 7 out-perform the state-of-the-art CVD low-k dielectric layers in terms of density and dielectric constant. In some embodiments, the low-k dielectric layers deposited using precursors shown in FIGS. 4, 6 and 7 has a density equal to or greater than 2.15 g/cm³, such as between about 2.15 g/cm³ and about 2.3 g/cm³, and a dielectric constant is equal to or smaller than 3.7, such as between about 3.4 and about 3.7.

Based on the foregoing, the present disclosure discloses method 10 for identifying a potential precursor for a low-k, high-density and etch-resistant dielectric layer. By using method 10, the present disclosure discloses a generic molecular structure 50 and two example precursors 52 and 54 that may be deposited using ALD to form low-dielectric-constant and high-density dielectric layer dielectric layers. Further, the present disclosure discloses method 60 for depositing a low-k, high-density and etch-resistant dielectric layer. The low-k dielectric layer deposited using method 60 and precursors of the present disclosure are suitable for implementation as a dielectric layer or a dielectric feature that withstands etching and remains in the final structure of a transistor structure to reduce parasitic capacitance. For example, the low-k, high-density and etch-resistant dielectric layer of the present disclosure may be used to form gate spacers or inner spacer features of multi-gate devices, such as fin-type field effect transistors (FinFETs), gate-all-around (GAA) transistors, and complementary field effect transistor (CFET).

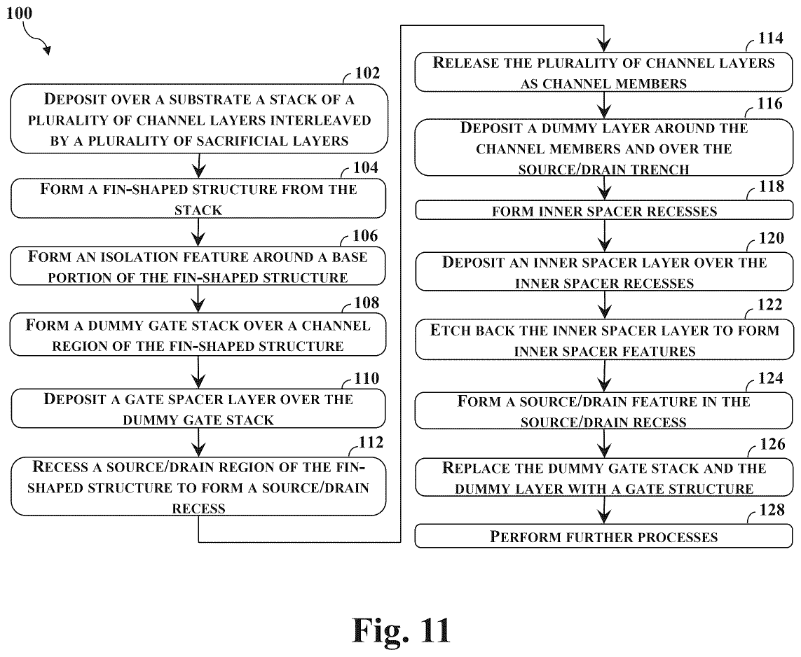

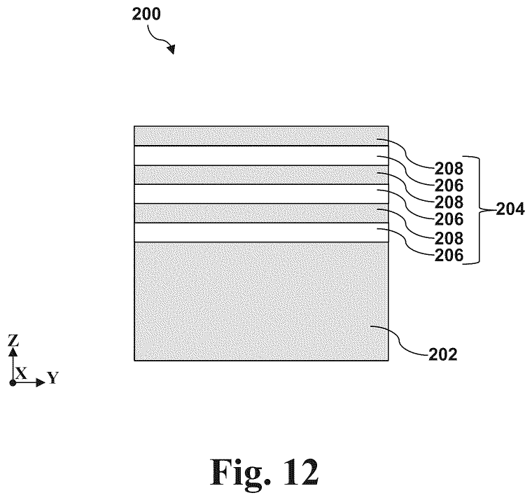

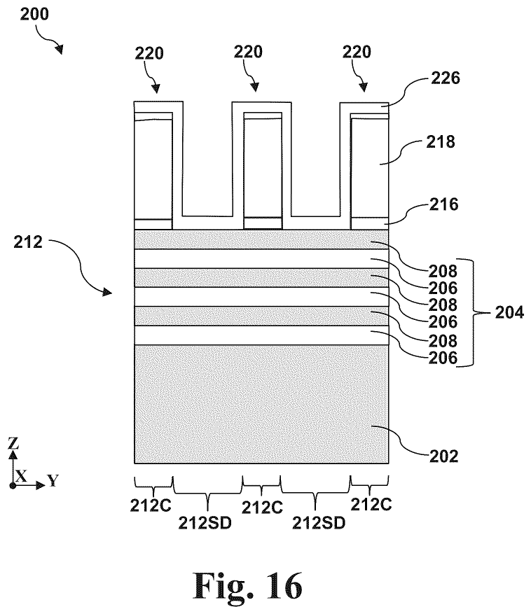

Reference is made to FIG. 11. The fourth aspect of the present disclosure is drawn to method 100 of forming a semiconductor structure from a work-in-progress (WIP) structure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 12-30, which are fragmentary cross-sectional views of a WIP structure 200 at different stages of fabrication according to embodiments of the method 100 in FIG. 11. Because the WIP structure 200 will be fabricated into a semiconductor structure or a semiconductor device, the WIP structure 200 may be referred to herein as a semiconductor structure 200 or a semiconductor device 200 as the context requires. For avoidance of doubts, the X, Y and Z directions in FIGS. 12-30 are perpendicular to one another. Throughout the present disclosure, unless expressly described otherwise, like reference numerals denote like features or steps.

Referring to FIGS. 11 and 12, method 100 includes a block 102 where a stack 204 of alternating semiconductor layers is formed over the WIP structure 200. As shown in FIG. 12, the WIP structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 12, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

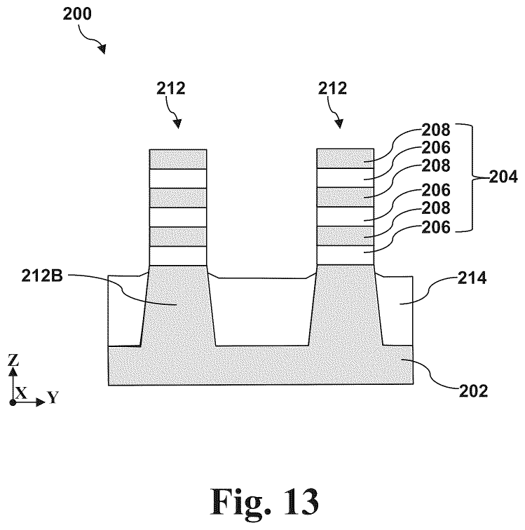

Referring to FIGS. 11 and 13, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 13, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 13, the fin-shaped structure 212 that includes the sacrificial layers 206 and the channel layers 208 extends vertically along the Z direction and lengthwise along the X direction. As shown in FIG. 13, the fin-shaped structure 212 includes a base fin structure 212B patterned from the substrate 202 and the patterned stack 204 disposed directly over the base fin structure 212B.

Referring to FIGS. 11 and 13, method 100 includes a block 106 where an isolation feature 214 is formed around a base fin structure 212B of the fin-shaped structures 212. In some embodiments represented in FIG. 13, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 13. The fin-shaped structure 212 rises above the STI feature 214 after the recessing, while the base fin structure 212B is embedded or buried in the isolation feature 214.

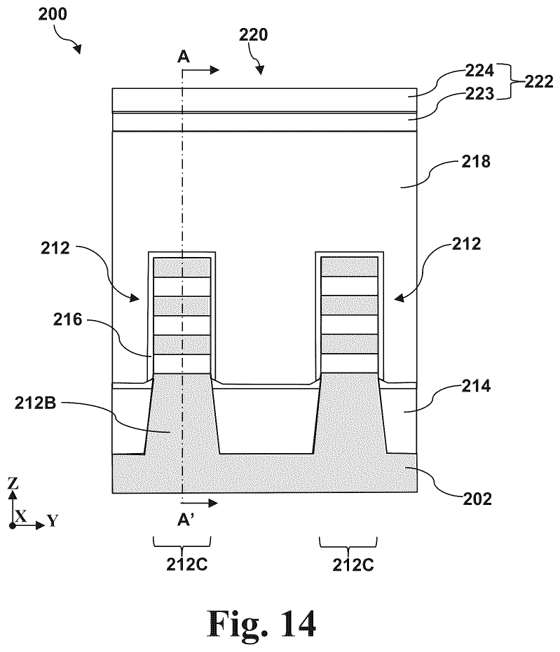

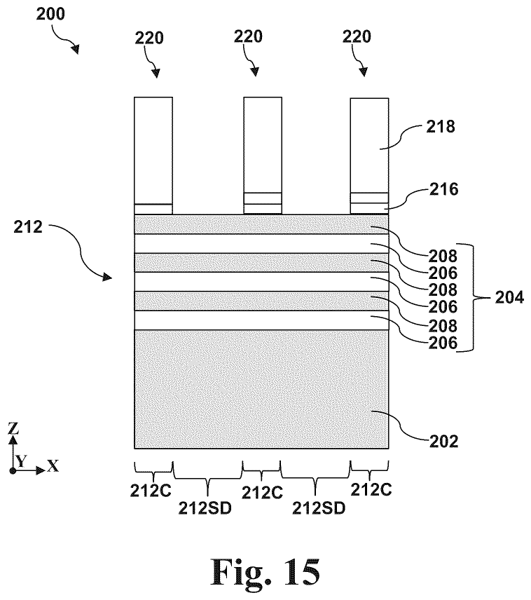

Referring to FIGS. 11, 14 and 15, method 100 includes a block 108 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. In some embodiments illustrated in FIG. 14, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 15, the channel region 212C is disposed between two source/drain regions 212SD along the X direction.

The formation of the dummy gate stack 220 may include deposition of layers in the dummy gate stack 220 and patterning of these layers. Referring to FIG. 14, a dummy dielectric layer 216, a dummy electrode layer 218, and a gate-top hard mask layer 222 may be blanketly deposited over the WIP structure 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes a surface layer of the fin-shaped structure 212 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 15. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 15, the dummy gate stack 220 is patterned such that it is only disposed over the channel region 212C, not disposed over the source/drain region 212SD.

Referring to FIGS. 11, 16 and 17, method 100 includes a block 110 where a gate spacer layer 226 is deposited over the WIP structure 200, including over the dummy gate stack 220. In some embodiments, the gate spacer layer 226 is deposited using the ALD process described in method 60 and precursors described above in conjunction with FIG. 4, 6 or 7. In one embodiment, the first example precursor 52 is used at block 112. In another embodiment, the second example precursor 54 is used at block 112. Due to the use of method 60 and example precursors, the gate spacer layer 226 includes silicon oxycarbonitride (SiOCN). In some embodiments, the gate spacer layer 226 includes a carbon content between about 5% and about 15% and a nitrogen content smaller than 10%. In the depicted embodiments, the gate spacer layer 226 has a density equal to or greater than 2.15 g/cm³, such as between about 2.15 g/cm³ and about 2.3 g/cm³, and a dielectric constant is equal to or smaller than 3.7, such as between about 3.4 and about 3.7. Due to the use of the example precursors and the densification step in method 60, the gate spacer layer 226 includes disilacyclobutane groups, silicon-carbon-oxygen-silicon (Si—C—O—Si) groups, or a combination thereof. In one embodiment, the gate spacer layer 226 includes disilacyclobutane groups.

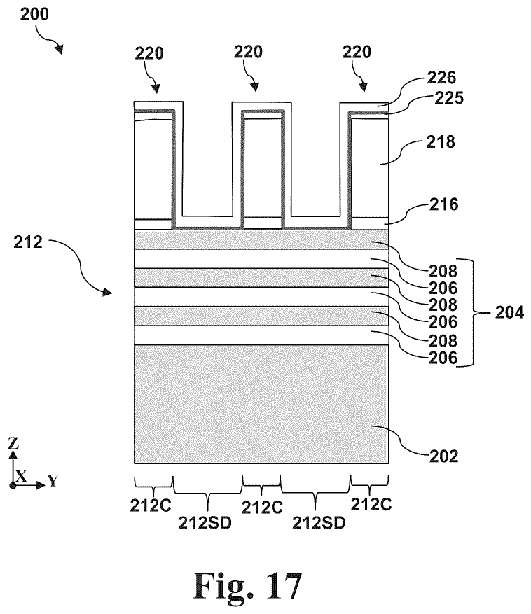

Reference is now made to FIG. 17, which illustrates a representative embodiment where an etch resistant spacer layer 225 is deposited over the WIP structure 200 before the deposition of the gate spacer layer 226. In some embodiments, the etch resistant spacer layer 225 may include silicon nitride or silicon carbonitride and may be deposited using ALD or PECVD. Compared to the gate spacer layer 226, the etch resistant spacer layer 225 is denser and more etch resistant. The added etch resistance helps help the integrity of the gate trench during removal of the dummy gate stack 220 and release of the channel layers 208 as channel members 2080. A dielectric constant of the etch resistant spacer layer 225 is greater than that of the gate spacer layer 226. In some instances, the etch resistant spacer layer 225 has a dielectric constant between about 4.8 and about 7. To reduce parasitic capacitance between the gate structure and the source/drain contact, a thickness of the etch resistant spacer layer 225 is smaller than a thickness of the gate spacer layer 226.

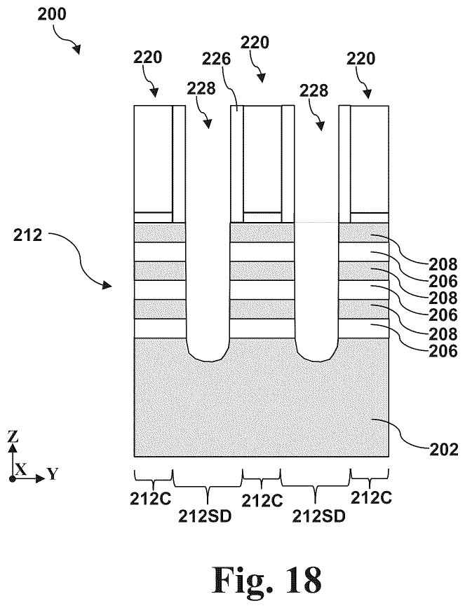

Referring to FIGS. 11 and 18, method 100 includes a block 112 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202. The resulting source/drain trench 228 extends vertically through the depth of the stack 204 and partially into the substrate 202. An example dry etch process for block 112 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 18, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

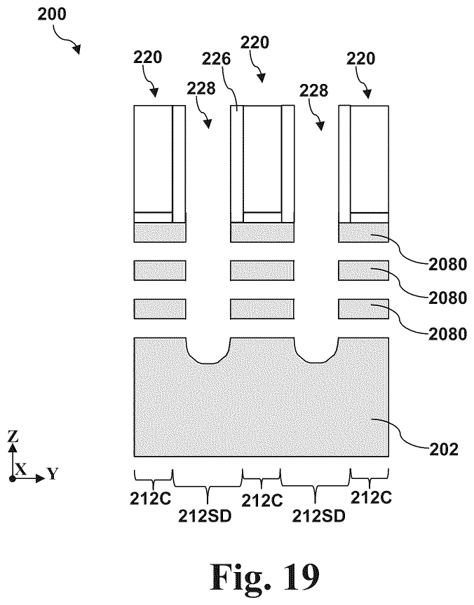

Referring to FIGS. 11 and 19, method 100 includes a block 114 where the plurality of channel layers 208 in the channel regions 212C are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 18) to form channel members 2080 shown in FIG. 19. The selective removal of the sacrificial layers 206 forms spaces between and around adjacent channel members 2080. Depending on the design, the channel members 2080 may take form of nanowires, nanosheets, or other nanostructures. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

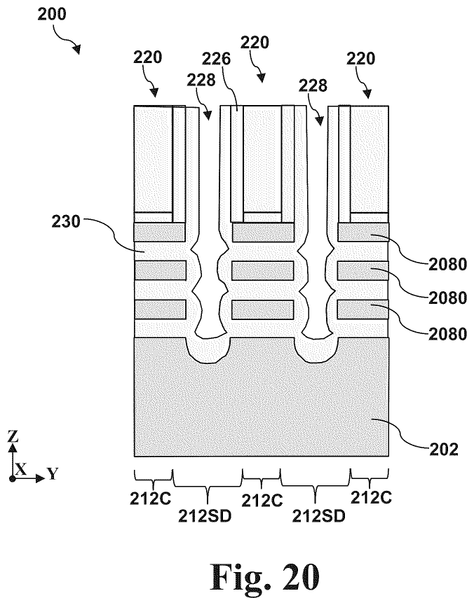

Referring to FIGS. 11 and 20, method 100 includes a block 116 where a dummy layer 230 is deposited around the channel members 2080 and over the source/drain trenches 228. The dummy layer 230 may include silicon oxide and may be deposited using plasma enhanced chemical vapor deposition (PECVD) or ALD. As shown in FIG. 20, the dummy layer 230 fills the space among the channel members 2080 and covers end sidewalls of the channel members 2080. Additionally, the dummy layer 230 is in direct contact with a sidewall of the gate spacer layer 226 and a top surface of the substrate 202.

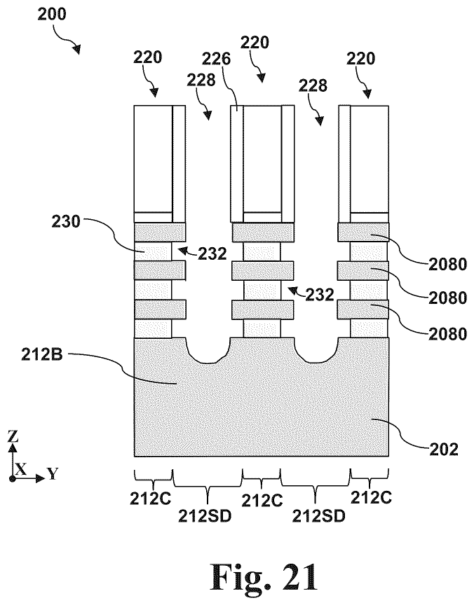

Referring to FIGS. 11 and 21, method 100 includes a block 118 where inner spacer recesses 232 are formed. Referring to FIG. 21, the dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective dry etching process may include use of carbon tetrafluoride (CF₄), gaseous hydrogen fluoride (HF), nitrogen trifluoride (NF₃), hydrogen (H₂), or a mixture thereof. An example selective wet etching process may include use of hydrofluoric acid, ammonium fluoride, or a mixture thereof.

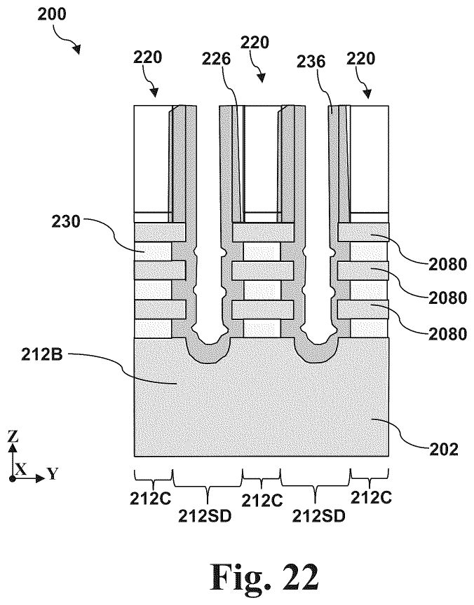

Referring to FIGS. 11 and 22, method 100 includes a block 120 where an inner spacer layer 236 is deposited over the inner spacer recesses 232. In some embodiments, the inner spacer layer 236 is deposited using the ALD process described in method 60 and precursors described above in conjunction with FIG. 4, 6 or 7. In one embodiment, the first example precursor 52 is used at block 120. In another embodiment, the second example precursor 54 is used at block 120. Due to the use of method 60 and example precursors, the inner spacer layer 236 includes silicon oxycarbonitride (SiOCN). In the depicted embodiments, the inner spacer layer 236 has a density equal to or greater than 2.15 g/cm³, such as between about 2.15 g/cm³ and about 2.3 g/cm³, and a dielectric constant is equal to or smaller than 3.7, such as between about 3.4 and about 3.7. Due to the use of the example precursors and the densification step in method 60, the inner spacer layer 236 includes disilacyclobutane groups, silicon-carbon-oxygen-silicon (Si—C—O—Si) groups, or a combination thereof. In one embodiment, the inner spacer layer 236 includes disilacyclobutane groups.

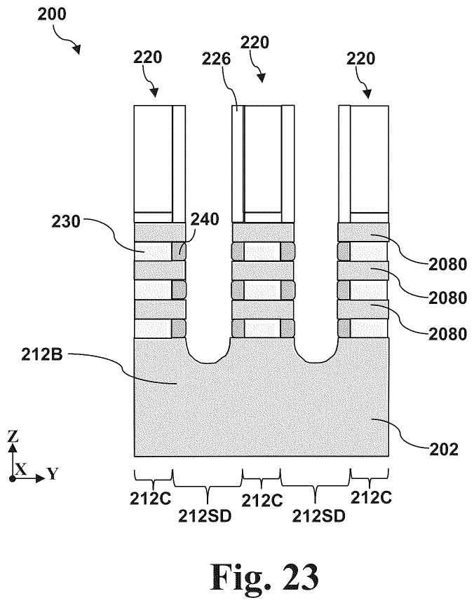

Referring to FIGS. 11 and 23, method 100 includes a block 122 where the inner spacer layer 236 is etched back to form inner spacer features 240 over the inner spacer recesses 232. Referring to FIG. 23, the deposited inner spacer layer 236 is then etched back to expose sidewalls of the channel members 2080, thereby forming inner spacer features 240 in the inner spacer recesses 232. In some embodiments, the etching back at block 122 may include use of a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof.

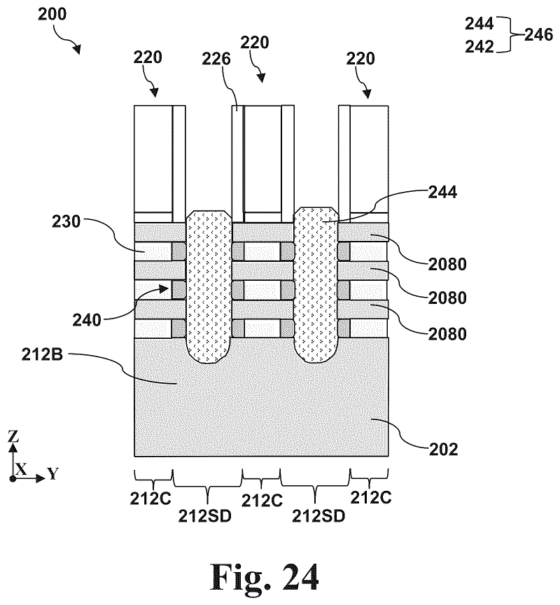

Referring to FIGS. 11 and 24, method 100 includes a block 124 where a source/drain feature 244 is formed over the source/drain region 212SD. While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

Reference is made to FIG. 24. The source/drain feature 244 may be n-type or p-type. When the source/drain feature 244 is n-type, it may include silicon (Si) and an n-type dopant, such as phosphorus (P), arsenic (As), antimony (Sb), or a combination thereof. When the source/drain feature 244 is p-type, it may include silicon germanium (SiGe) and a p-type dopant, such as boron (B), boron difluoride (BF₂), or a combination thereof. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping.

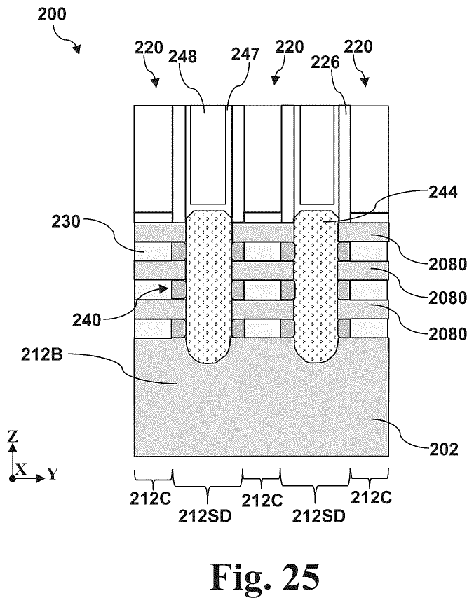

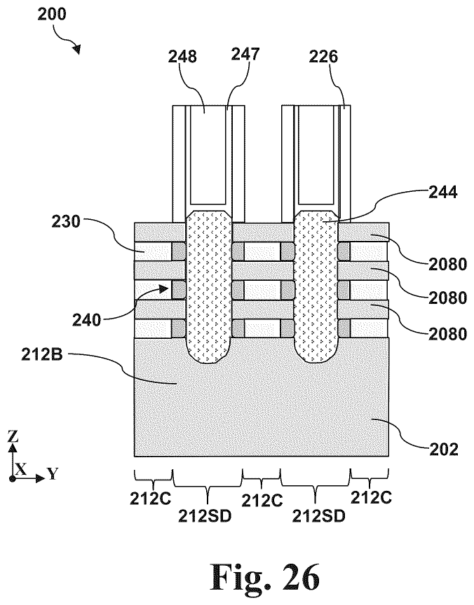

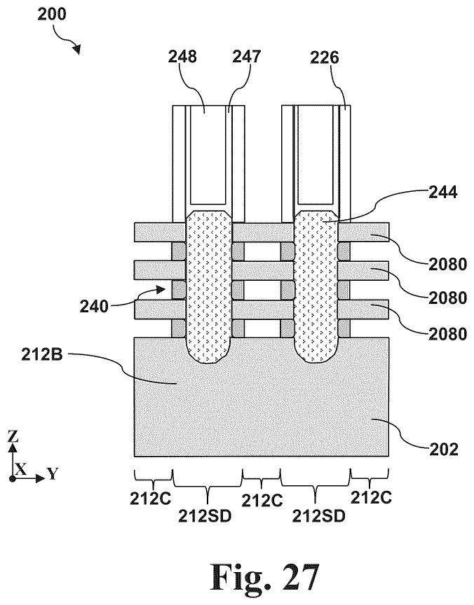

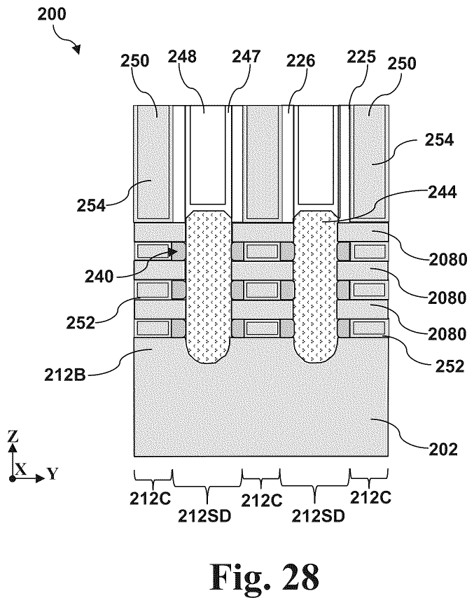

Referring to FIGS. 11 and 25-28, method 100 includes a block 126 where the dummy gate stack 220 and the dummy layer 230 are replaced with a gate structure 250. Operations at block 126 may include deposition of a contact etch stop layer (CESL) 247 over the source/drain features 246 (shown in FIG. 25), deposition of an interlayer dielectric layer 248 over the CESL 247 (shown in FIG. 25), removal of the dummy gate stack 220 (shown in FIG. 26), removal of the dummy layer 230 (shown in FIG. 27), and deposition of the gate structure 250 to wrap around each of the channel members 2080 (shown in FIG. 28). Referring to FIG. 25, the CESL 247 is deposited over the WIP structure 200, including over the source/drain feature 246. The CESL 247 may include silicon nitride or aluminum nitride. In some implementations, the CESL 247 may be deposited using CVD or atomic layer deposition (ALD). The ILD layer 248 is then deposited over the CESL 247. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the WIP structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220.

After the removal of the dummy gate stack 220, the dummy layer 230 in the channel region 212C is exposed. A separate etch process may be performed to selectively remove the dummy layer 230 in the channel region 212C. For example, a selective wet etch process or a selective dry etch process may be performed to remove the dummy layer 230. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the selective removal of the dummy layer 230, the channel members 2080 in the channel region 212C are once again exposed as shown in FIG. 27.

After the release of the channel members 2080, the gate structure 250 is formed to wrap around each of the channel members 2080 as shown in FIG. 28. The gate structure 250 includes an interfacial layer interfacing the channel members 2080 and the substrate 202 in the channel region 212C, a gate dielectric layer 252 over the interfacial layer, and a gate electrode layer 254 over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer 252 may include a high-k dielectric material, such as hafnium oxide (HfO). Alternatively, the gate dielectric layer 252 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. In some instances, the gate dielectric layer 252 has a dielectric constant greater than 9, such as between 9 and 25. The gate dielectric layer 252 may be formed by ALD, physical vapor deposition (PVD), CVD, oxidation, and/or other suitable methods.

The gate electrode layer 254 of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 254 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 254 may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

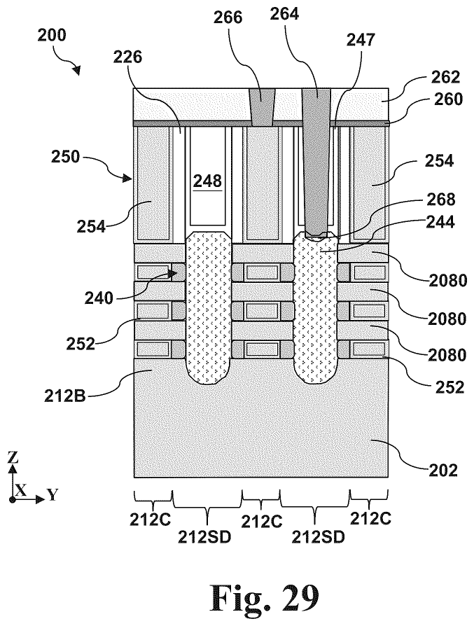

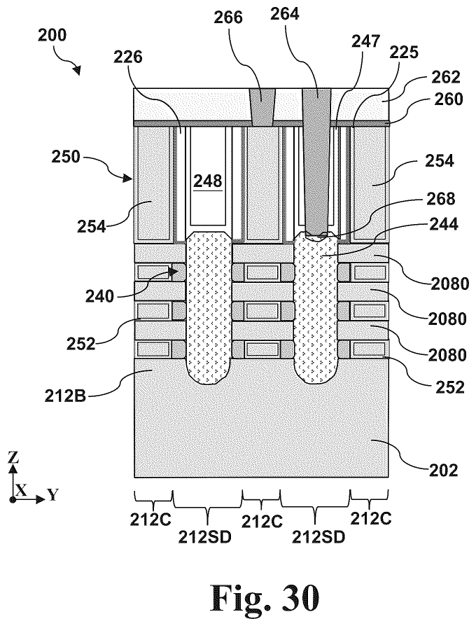

Referring to FIGS. 11, 29 and 30, method 100 includes a block 128 where further processes are performed. Such further processes may include formation of middle-end-of-line (MEOL) structures. At block 128, an etch stop layer (ESL) 260 may be deposited over the WIP structure 200 and an upper interlayer dielectric (ILD) layer 262 may be deposited over the ESL 260. The ESL 260 may be a single layer or a multi-layer and may be deposited using ALD or CVD. In some embodiments, the ESL 260 may include aluminum nitride (AlN), silicon nitride (SiN), aluminum oxide (AlO), or a combination thereof. The composition and formation of the upper ILD layer 262 may be similar to those of the ILD layer 248. As shown in FIG. 29, a gate contact 266 may be formed to extend through the upper ILD layer 262 and the ESL 260 to couple to the gate electrode 254 of the gate structure 250. The gate contact 266 may include tungsten (W) or ruthenium (Ru). A source/drain contact 264 may be formed to extend through the upper ILD layer 262, the ESL 260, the ILD layer 248, and the CESL 247 to couple to the source/drain feature 244 by way of a silicide feature 268. In some embodiments, the source/drain contact 264 may include tungsten (W), cobalt (Co), nickel (Ni), or a combination thereof. The silicide feature 268 may include titanium silicide, tantalum silicide, tungsten silicide, cobalt silicide, or nickel silicide. FIG. 30 illustrates an alternative structure where the etch resistant spacer layer 225 is deposited before the deposition of the gate spacer layer 226.

Upon conclusion of the operations at block 128, a semiconductor structure 200 is formed from the WIP structure 200. It is noted that both the gate spacer layer 226 and the inner spacer features 240 remain in the semiconductor structure 200. As describe above, the gate spacer layer 226 and the inner spacer features 240 may include disilacyclobutane groups, silicon-carbon-oxygen-silicon (Si—C—O—Si) groups, or a combination thereof. In one embodiment, the gate spacer layer 226 and the inner spacer features 240 may include disilacyclobutane groups. Compared to the isolation feature 214 and the ILD layer 248 that are formed of regular low-k dielectric layers, the gate spacer layer 226 and the inner spacer features 240 have a greater density and greater etch resistance against dry etching process that uses halogen-containing species.

In one exemplary aspect, the present disclosure is directed to a method. The method includes depositing a precursor on a material layer, oxidizing the precursor on the material layer, and performing a plasma treatment of the oxidized precursor to form a low dielectric constant (low-k) dielectric layer. The precursor includes a disilacyclobutane backbone.

In some embodiments, the precursor includes 1,1,3,3-tetrachloro-1,3-disilacyclobutane or 1,3-bis(dimethylamino)-1,3-ethoxyl-1,3-disilacyclobutane. In some implementations, the material layer includes a semiconductor material or a dielectric material. In some instances, the material layer includes hydroxyl groups. In some embodiments, the oxidizing includes a thermal oxidation process or a plasma oxidation process, the thermal oxidation process includes use of an oxygen-containing reagent, and the plasma oxidation process includes use of an oxygen-free reagent. In some embodiments, the depositing of the precursor includes use of atomic layer deposition (ALD). In some embodiments, the low-k dielectric layer includes a dielectric constant between about 3.4 and about 3.7. In some instances, the low-k dielectric layer includes a density between about 2.15 g/cm³ and about 2.3 g/cm³.

In another exemplary aspect, the present disclosure is directed to a method. The method includes forming, over a substrate, a stack including a plurality of channel layers interleaved by a plurality of sacrificial layers, forming a fin-shaped structure from a portion of the substrate and the stack, forming a dummy gate stack over a channel region of the fin-shaped structure, after the forming of the dummy gate stack, depositing a gate spacer layer over the dummy gate stack and the substrate, forming a source/drain recess over a source/drain region of the fin-shaped structure, selectively and partially etching the plurality of sacrificial layers to form inner spacer recesses, depositing an inner spacer layer over the inner spacer recesses, anisotropically etching the inner spacer layer to form inner spacer features in the inner spacer recesses, forming a source/drain feature in the source/drain recess, removing the dummy gate stack, selectively removing the plurality of sacrificial layers in the channel region to release the plurality of channel layers as a plurality of channel members, and forming a gate structure to wrap around each of the plurality of channel members. The depositing of the gate spacer layer includes depositing a first precursor over the dummy gate stack and the substrate, oxidizing the first precursor over the dummy gate stack and the substrate, and densifying the oxidized first precursor to form the gate spacer layer. The first precursor includes a disilacyclobutane backbone.

In some embodiments, The method of claim 9, wherein the depositing of the inner spacer layer includes depositing a second precursor over the inner spacer recesses, oxidizing the second precursor over the inner spacer recesses, and densifying the oxidized second precursor to form the inner spacer features. The second precursor includes a disilacyclobutane backbone. In some embodiments, the first precursor and the second precursor include 1,1,3,3-tetrachloro-1,3-disilacyclobutane or 1,3-bis(dimethylamino)-1,3-ethoxyl-1,3-disilacyclobutane. In some implementations, the oxidizing includes a thermal oxidation process or a plasma oxidation process, the thermal oxidation process includes use of an oxygen-containing reagent, and the plasma oxidation process includes use of an oxygen-free reagent. In some embodiments, the densifying includes treating the oxidized first precursor with a remotely generated plasma. In some embodiments, the remotely generated plasma includes hydrogen. In some embodiments, the depositing of the first precursor includes use of atomic layer deposition (ALD).

In yet another exemplary aspect, the present disclosure is directed to a semiconductor structure. The semiconductor structure includes a channel region over a substrate, a gate structure over the channel region and including a gate dielectric layer and a gate electrode over the gate dielectric layer, a source/drain feature interfacing the channel region, a source/drain contact over the source/drain feature, and a gate spacer disposed between the gate structure and the source/drain contact. The gate spacer includes disilacyclobutane functional groups.

In some embodiments, the channel region includes a plurality of nanostructures stacked one over another and the gate structure wraps around each of the plurality of nanostructures. In some embodiments, the semiconductor structure further includes a plurality of inner spacer features interleaving the plurality of nanostructures. The source/drain feature is spaced apart from the gate structure by the plurality of inner spacer features and the plurality of inner spacer features includes disilacyclobutane functional groups. In some embodiments, the semiconductor structure further includes an isolation feature disposed over the substrate and adjacent the channel region. A density of the gate spacer is greater than a density of the isolation feature and a dielectric constant of the gate spacer is smaller than a dielectric constant of the isolation feature. In some embodiments, the semiconductor structure further includes an interlayer dielectric (ILD) layer over the source/drain feature. A density of the gate spacer is greater than a density of the ILD layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a precursor on a material layer;
oxidizing the precursor on the material layer; and
performing a plasma treatment of the oxidized precursor to form a low dielectric constant (low-k) dielectric layer,
wherein the precursor comprises a disilacyclobutane backbone.

2. The method of claim 1, wherein the precursor comprises 1,1,3,3-tetrachloro-1,3-disilacyclobutane or 1,3-bis(dimethylamino)-1,3-ethoxyl-1,3-disilacyclobutane.

3. The method of claim 1, wherein the material layer comprises a semiconductor material or a dielectric material.

4. The method of claim 1, wherein the material layer comprises hydroxyl groups.

5. The method of claim 1,
wherein the oxidizing comprises a thermal oxidation process or a plasma oxidation process,
wherein the thermal oxidation process comprises use of an oxygen-containing reagent,
wherein the plasma oxidation process comprises use of an oxygen-free reagent.

6. The method of claim 1, wherein the depositing of the precursor comprises use of atomic layer deposition (ALD).

7. The method of claim 1, wherein the low-k dielectric layer comprises a dielectric constant between about 3.4 and about 3.7.

8. The method of claim 1, wherein the low-k dielectric layer comprises a density between about 2.15 g/cm³ and about 2.3 g/cm³.

9. A method, comprising:
forming, over a substrate, a stack comprising a plurality of channel layers interleaved by a plurality of sacrificial layers;
forming a fin-shaped structure from a portion of the substrate and the stack;
forming a dummy gate stack over a channel region of the fin-shaped structure;
after the forming of the dummy gate stack, depositing a gate spacer layer over the dummy gate stack and the substrate;
forming a source/drain recess over a source/drain region of the fin-shaped structure;
selectively and partially etching the plurality of sacrificial layers to form inner spacer recesses;
depositing an inner spacer layer over the inner spacer recesses;
anisotropically etching the inner spacer layer to form inner spacer features in the inner spacer recesses;
forming a source/drain feature in the source/drain recess;
removing the dummy gate stack;
selectively removing the plurality of sacrificial layers in the channel region to release the plurality of channel layers as a plurality of channel members; and
forming a gate structure to wrap around each of the plurality of channel members,
wherein the depositing of the gate spacer layer comprises:
depositing a first precursor over the dummy gate stack and the substrate,
oxidizing the first precursor over the dummy gate stack and the substrate, and
densifying the oxidized first precursor to form the gate spacer layer,
wherein the first precursor comprises a disilacyclobutane backbone.

10. The method of claim 9, wherein the depositing of the inner spacer layer comprises:
depositing a second precursor over the inner spacer recesses,
oxidizing the second precursor over the inner spacer recesses, and
densifying the oxidized second precursor to form the inner spacer features,
wherein the second precursor comprises a disilacyclobutane backbone.

11. The method of claim 10, wherein the first precursor and the second precursor comprise 1,1,3,3-tetrachloro-1,3-disilacyclobutane or 1,3-bis(dimethylamino)-1,3-ethoxyl-1,3-disilacyclobutane.

12. The method of claim 9,
wherein the oxidizing comprises a thermal oxidation process or a plasma oxidation process,
wherein the thermal oxidation process comprises use of an oxygen-containing reagent,
wherein the plasma oxidation process comprises use of an oxygen-free reagent.

13. The method of claim 9, wherein the densifying comprises treating the oxidized first precursor with a remotely generated plasma.

14. The method of claim 13, wherein the remotely generated plasma comprises hydrogen.

15. The method of claim 9, wherein the depositing of the first precursor comprises use of atomic layer deposition (ALD).

16. A semiconductor structure, comprising:
a channel region over a substrate;
a gate structure over the channel region and comprising a gate dielectric layer and a gate electrode over the gate dielectric layer;
a source/drain feature interfacing the channel region;
a source/drain contact over the source/drain feature; and
a gate spacer disposed between the gate structure and the source/drain contact,
wherein the gate spacer comprises disilacyclobutane functional groups.

17. The semiconductor structure of claim 16,
wherein the channel region comprises a plurality of nanostructures stacked one over another,
wherein the gate structure wraps around each of the plurality of nanostructures.

18. The semiconductor structure of claim 17, further comprising:
a plurality of inner spacer features interleaving the plurality of nanostructures,
wherein the source/drain feature is spaced apart from the gate structure by the plurality of inner spacer features,
wherein the plurality of inner spacer features comprises disilacyclobutane functional groups.

19. The semiconductor structure of claim 16, further comprising:
an isolation feature disposed over the substrate and adjacent the channel region,
wherein a density of the gate spacer is greater than a density of the isolation feature,
wherein a dielectric constant of the gate spacer is smaller than a dielectric constant of the isolation feature.

20. The semiconductor structure of claim 16, further comprising:
an interlayer dielectric (ILD) layer over the source/drain feature,
wherein a density of the gate spacer is greater than a density of the ILD layer.
